(19) United States
(12) Patent Application Publication
(10) Pub. No.: US 2009/0145644 A1
(43) Pub. Date: Jun. 11, 2009

(54) Printed wiring board, air conditioner, and method of soldering printed wiring board

(75) Inventor: Tsuyoshi Miura, Tokyo (JP)

Correspondence Address: BUCHANAN, INGERSOLL & ROONEY PC, POST OFFICE BOX 1404, ALEXANDRIA, VA, 22313-1404, US

(73) Assignee: Mitsubishi Electric Corporation, Chiyoda-ku (JP)

(21) Appl. No.: 12/219,530

(22) Filed: Jul. 23, 2008

(30) Foreign Application Priority Data
Dec. 6, 2007 (JP) 2007-315713

(51) Int. Cl. H05K 1/16; B23K 1/08

(52) U.S. Cl. 174/260; 228/36

(57) ABSTRACT

To provide a printed wiring board capable of completely soldering a solder land to a lead under simple control over a manufacturing process even in the case of using a lead-free solder of a low solder wettability. A printed wiring board for mounting a surface mounting device includes a solder land for mounting the surface mounting device, and a leader pattern led from the solder land with only a predetermined portion of the leader pattern being soldered.

### BACKGROUND OF THE INVENTION

1. Field of the Invention

The present invention relates to a printed wiring board for mounting a surface mounting device thereto, a method of soldering the printed wiring board, and an air conditioner housing the printed wiring board.

2. Description of the Related Art

Generally speaking, there is an increasing demand to increase a packaging density of electronic components on a printed wiring board. In response to the demand, it is necessary to package small surface mounting devices with a high density.

On the other hand, in consideration of a recent environmental issue, an essential condition for soldering is to use a lead-free solder. However, the lead-free solder is inferior in solderability due to lower wettability than that of a conventional lead-contained eutectic solder. As a result, a solder land for a surface mounting device and a lead are not soldered because of rejecting a solder and thus not connected together.

Up to now, there has been proposed a technique for soldering the printed wiring board, which aims at “accelerating the spread of a solder flux based on a capillary phenomenon to increase a wettability”. According to this technique, “on a printed wiring board 1 where a land 4a is formed on a part of a conductor pattern, a plurality of slits 5 for controlling the spread of a flux 8 are formed throughout the land 4a, and the flux 8 spreads over the land 4a along the slits 5 due to a capillary phenomenon (see Japanese Unexamined Patent Application Publication No. 2006-313792).

On the other hand, there has been proposed a technique regarding a wave soldering apparatus, which aims at “preventing a solder crack etc. to improve a solder quality”. This technique proposes “a wave soldering apparatus supplying a molten solder 10 under pressure toward jet guides 1 and 2 using a pressure device, and passing a printed board 3 through the molten solder 10 injected from the jet guides 1 and 2 to execute soldering, which brings the molten solder 10 jetting from the jet guides 1 and 2 obliquely upwards toward the opposite direction of a moving direction A of the printed board 3, and thus applies the molten solder 10 onto a rear side of the printed board 3. Thus, a component force is generated vertically upwards to prevent the molten solder 10 from falling down under its weight to prevent a solder crack after long-term use. In addition, the molten solder 10 is removed from the board 3 in almost the same position as a solder applying position, so a solder removing position can be secured with a stability and a bridge etc. can be prevented to improve a solder quality. Further, the molten solder 10 is continuously sprayed to a board soldering portion, so voids that would be formed due to the remaining molten solder 10 are reduced” (see Japanese Unexamined Patent Application Publication No. H10-173329).

According to the technique disclosed in Japanese Unexamined Patent Application Publication No. 2006-313792, a manufacturing process should be carefully managed in order to prevent a solder land and a lead from rejecting a solder and being unsoldered and to realize soldering with a high quality. In the case of using a lead-free solder having a low solder wettability, it is difficult to accurately solder the board.

### SUMMARY OF THE INVENTION

The present invention has been accomplished to solve the above problems. Accordingly, it is an object of the present invention to provide a printed wiring board capable of completely soldering a solder land to a lead under simple control over a manufacturing process even in the case of using a lead-free solder having a low solder wettability.

According to the present invention, a printed wiring board for mounting a surface mounting device includes a solder land for mounting the surface mounting device, and a leader pattern led from the solder land, wherein only a predetermined portion of the leader pattern is soldered.

According to the printed wiring board of the present invention, a leader pattern is led from a solder land so as to solder only a predetermined portion of the leader pattern. Thus, the board has an effect of drawing a solder into the solder land upon a soldering process, so the solder land and a lead can be completely soldered.

### BRIEF DESCRIPTION OF THE DRAWINGS

FIG. 1 is a plan view of a schematic layout as viewed from a rear side of a printed wiring board according to a first embodiment of the present invention;

FIG. 2 is an enlarged view of a peripheral portion of a surface mounting device of the printed wiring board of the first embodiment;

FIG. 3 is a flowchart of a process for soldering the surface mounting device to the printed wiring board of the first embodiment with a wave soldering apparatus.

FIG. 4 is an enlarged view of a peripheral portion of the surface mounting device of the printed wiring board according to a second embodiment of the present invention; and

FIG. 5 is a front view of an outdoor unit of an air conditioner according to a fourth embodiment of the present invention.

### DESCRIPTION OF THE PREFERRED EMBODIMENTS

### First Embodiment

FIG. 1 is a plan view showing a schematic layout of a printed wiring board 1 according to a first embodiment of the present invention as viewed from the rear side thereof. FIG. 1 shows the structure of arranged mounting devices including a surface mounting device 2.

On the printed wiring board 1, components to be automatically mounted to a surface thereof and components to be manually inserted are arranged.

Examples of the components to be automatically mounted include a chip component resistor, a chip component capacitor, a chip component diode, a discrete resistor, a discrete capacitor, and a discrete diode (none of the components are illustrated).

Examples of the components to be manually inserted include a large-capacity resistor, a hybrid IC, a transformer, a coil, a large-capacity semiconductor, and a large-capacity capacitor (none of the components are illustrated).

A rear side of the printed wiring board 1 is covered with a copper foil (not shown).

Further, the surface mounting device 2 is automatically mounted vertically with respect to a flowing direction of a wave soldering apparatus (“direction in which a wave soldering process progresses” as indicated by the arrow of FIG. 1) so as to keep the rear side of the printed wiring board 1 being flat as mush as possible.

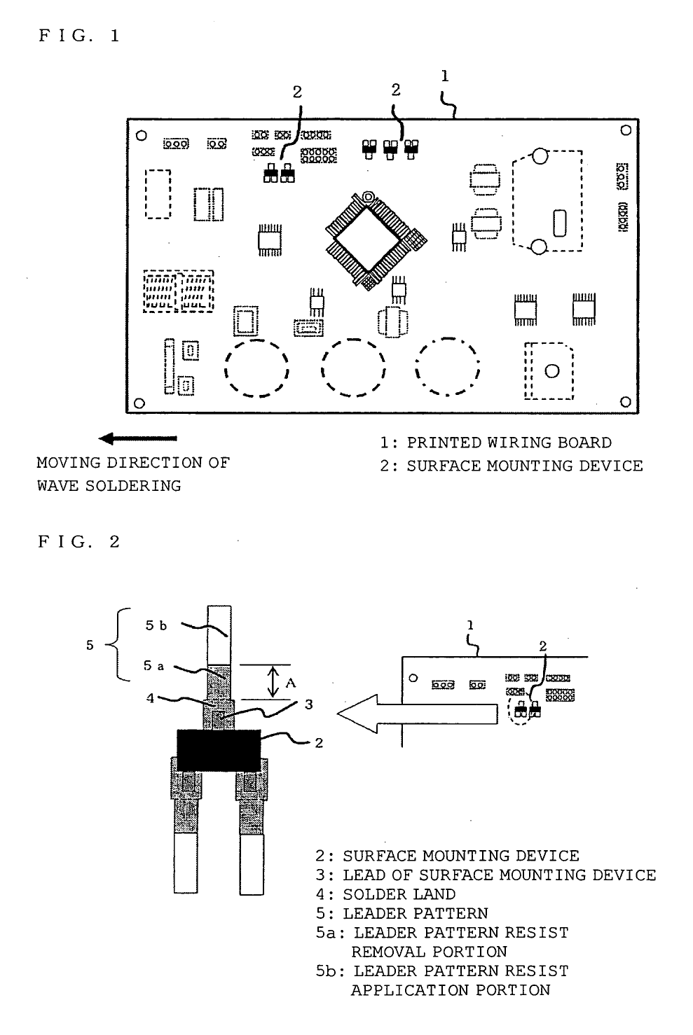

FIG. 2 is an enlarged view of a peripheral portion of the surface mounting device 2 of the printed wiring board 1 according to a first embodiment of the present invention.

On the printed wiring board 1, a solder land 4 and a leader pattern 5 are formed.

The solder land 4 is used to connect a lead 3 of the solder mounting device 2 to the printed wiring board 1.

The leader pattern 5 is led from the solder land 4 for establishing electric connection.

The leader pattern 5 is composed of a leader pattern resist removal portion 5a and a leader pattern resist application portion 5b.

A solder resist is removed from the leader pattern resist removal portion 5a to apply a solder thereto.

The leader pattern resist application portion 5b is electrically connected to the leader pattern resist removal portion 5a and applied with a resist so as not to solder the leader pattern resist application portion 5b.

Components of the printed wiring board 1 of the first embodiment differ from a surface mounting device attaching land of a conventional printed wiring board in that a resist on the leader pattern 5 led from the land is partially removed.

A length of the leader pattern resist removal portion 5a (“A” of FIG. 2) is preferably almost the same as or twice as long as that of the solder land 4.

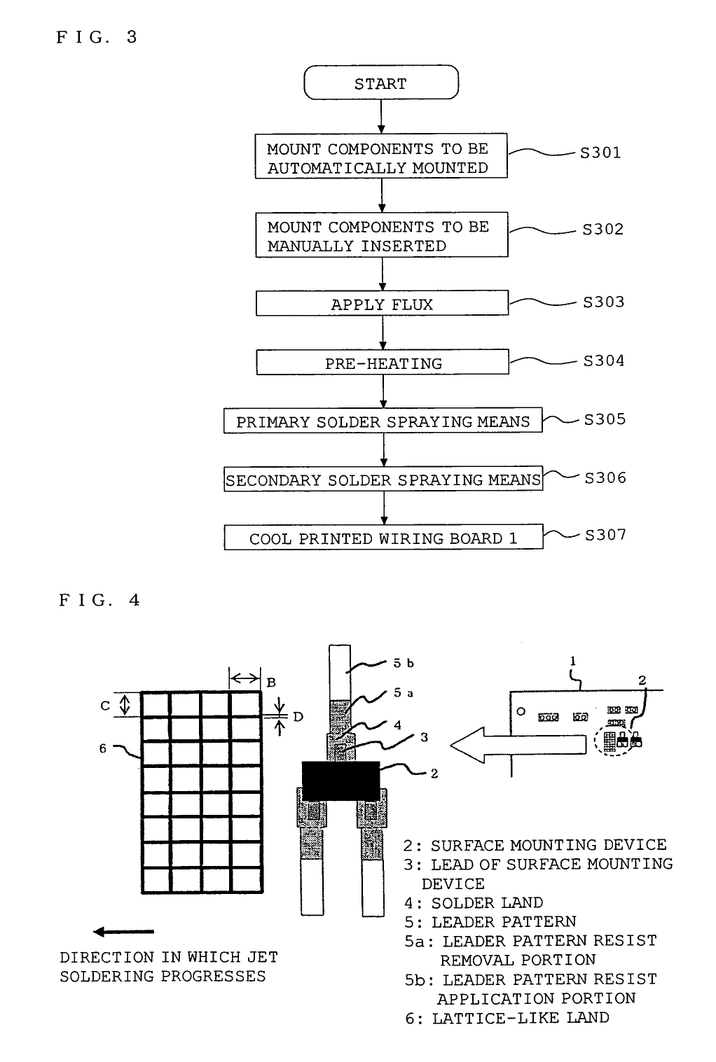

FIG. 3 is a flowchart of a process for soldering the surface mounting device 2 to the printed wiring board 1 using a wave soldering apparatus. Each step of the process is described below.

(S301) The components to be automatically mounted are mounted to the front and rear sides of the printed wiring board 1 using an automatic mounting device.

(S302) The components to be manually inserted are manually inserted and mounted to the surface of the printed wiring board 1.

(S303) A flux activator is applied to the rear side of the printed wiring board 1 so as to spread a solder over a copper foil.

(S304) Heating is performed prior to soldering at the best activation temperature of the flux applied in step S303.

(S305) Primary solder spraying means of the wave soldering apparatus sprays a solder from many nozzles to the rear side of the printed wiring board 1 having the surface mounting device 2 mounted thereonto to uniformly apply a solder to the lead 3 of the surface mounting device 2. Any type of solder can be used in this example, but a lead-free solder is preferred in consideration of the object of the present invention.

Note that examples of the structure of the wave soldering apparatus and the soldering process are described in Japanese Unexamined Patent Application Publication No. H10-173329.

(S306) After the completion of the soldering process with the primary solder spraying means in step S305, secondary solder spraying means of the wave soldering apparatus removes a solder sprayed with the primary solder spraying means and bridged between leads of the components.

(S307) The printed wiring board 1 having the surface mounting device 2 soldered thereto is cooled and the solder is secured.

The process for soldering the surface mounting device 2 to the printed wiring board 1 is described above.

Next, an effect of the leader pattern 5 illustrated in FIG. 2 during the soldering process is described.

In the soldering process with the wave soldiering apparatus, if the surface mounting device 2 is passed through a solder spraying portion of a jet solder tank, the solder flows backwards along the solder land 4.

At this time, the solder flows along the lead 3. The lead 3 repels the solder. In particular, a lead-free solder with a large surface tension is low in wettability with respect to the lead 3 and rejected. Thus, its solderability is low.

To that end, the leader pattern resist removal portion 5a illustrated in FIG. 2 is formed to easily draw the solder into the solder land 4. As a result, unsoldered portions of the solder land 4 can be considerably reduced.

The inventors of the present invention has confirmed that if the resist on the leader pattern 5 is applied, not removed as in the conventional examples, a very large portion of the solder land 4 remains unsoldered compared with the first embodiment.

As described above, in the first embodiment, the leader pattern resist removal portion 5a not covered with a resist is partially formed in the leader pattern 5.

Thus, the leader pattern resist removal portion 5a can easily attracts the solder, which produces an effect of easily drawing the solder into the solder land 4. Accordingly, even in the case of using a lead-free solder with low solder wettability, unsoldered portions can be reduced.

### Second Embodiment

FIG. 4 is an enlarged view of a peripheral portion of the surface mounting device 2 of the printed wiring board 1 according to a second embodiment of the present invention.

In FIG. 4, a lattice-like land 6 is additionally formed in front of the solder land 4 for soldering the surface mounting device 2. The other structure is the same as that of the first embodiment as illustrated in FIG. 2. Thus, its description is omitted. The term “in front of” means “in front of” the surface mounting device 2 as viewed in a moving direction of the wave soldering apparatus.

“A solder surface tension reducing land” of the second embodiment corresponds to the lattice-like land 6.

Components of the printed wiring board 1 of the second embodiment differ from a surface mounting device mounting land of the conventional printed wiring board in that the lattice-like land 6 is additionally formed in front of the surface mounting device 2 as viewed in a moving direction of the wave soldering apparatus in addition to the difference described in the first embodiment.

The lattice-like land 6 preferably has a vertical size almost the same as or twice as that of the surface mounting device 2 and a horizontal size almost the same as or twice as that of the surface mounting device 2.

The structure of the printed wiring board 1 of the second embodiment is described above.

Next, an effect of the lattice-like land 6 illustrated in FIG. 4 during the soldering process is described. The soldering process is similar to that of the first embodiment as illustrated in FIG. 3, so its description is omitted.

In the soldering process using the wave soldering apparatus, if the surface mounting device 2 is passed through a solder spraying portion of the jet solder tank, the solder flows backward along the lattice-like land 6 and the solder land 4.

At this time, the solder is applied to each lattice pattern in front of the surface mounting device 2, so the lattice-like land 6 has an effect of reducing a surface tension of the solder and drawing the solder from the peripheral portion of the solder land 4 as well as a dispersion effect on the surface tension of the drawn solder. If the surface tension of the solder is dispersed and reduced, solder wettability is increased and solderability is improved, so unsoldered portions of the solder land 4 are considerably reduced.

The inventors of the present invention has confirmed that a very large portion of the solder land 4 remains unsoldered in the conventional printed wiring board not provided with the lattice-like land 6 as compared with the second embodiment in which the lattice-like land 6 is formed.

The effect of the lattice-like land 6 is described above.

The structure including the lattice-like land 6 in addition to the structure including the leader pattern resist removal portion 5a in the first embodiment as illustrated in FIG. 2 is described in the second embodiment as illustrated in FIG. 4. Note that even in the case of forming the lattice-like land 6 in the structure of the leader pattern 5 not including the leader pattern resist removal portion 5a as in the conventional examples, the lattice-like land 6 achieves an effect similar to that of the second embodiment.

In the second embodiment, the lattice-like land 6 is additionally formed, but its shape is not limited to the lattice shape, and a similar effect can be achieved with any other shape as long as a solder can be drawn and a surface tension can be dispersed.

As described above, in the second embodiment, the lattice-like land 6 is formed in front of the surface mounting device 2 as viewed from the moving direction of the wave soldering apparatus to reduce a surface tension of a solder, so unsoldered portions of the solder land 4 can be considerably reduced, which produces an effect of omitting a subsequent step of manually adjusting the unsoldered portions.

### Third Embodiment

The lattice-like land 6 of the second embodiment as illustrated in FIG. 4 may be formed in front of each mounting position of the surface mounting device 2. However, even if the lattice-like land 6 is formed only in front of some of the surface mounting devices 2, a surface tension dispersion effect can be exerted to a certain degree.

For example, the lattice-like land may be formed only in front of the foremost surface mounting device 2 in a direction in which a wave soldering process progresses.

In the case of forming the lattice-like land 6 only in front of some of the surface mounting devices 2, the number of steps of forming the lattice-like lands 6 can be advantageously reduced, a space can be saved, and a surface tension dispersion effect can be exerted to a certain degree as compared with the case of forming the lattice-like land 6 in front of all of the surface mounting devices 2.

It is appropriately determined where to form the lattice-like land 6 by examining the wiring structure of the printed wiring board 1 or a solder material.

### Fourth Embodiment

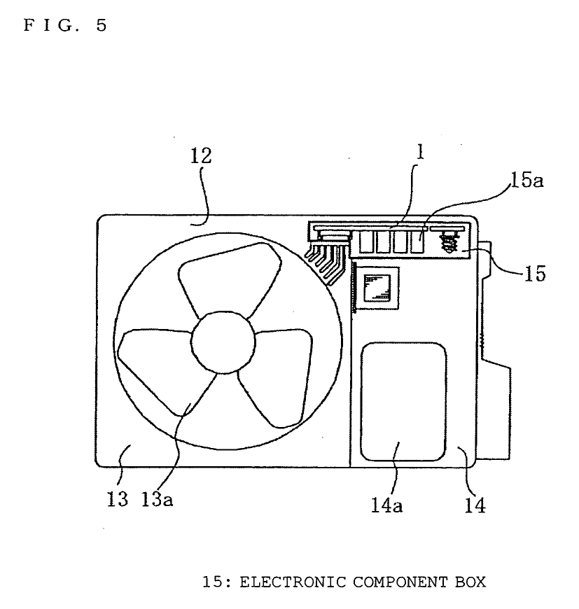

FIG. 5 is a front view of an outdoor unit 12 of an air conditioner according to a fourth embodiment of the resent invention.

In FIG. 5, the outdoor unit 12 includes a fan chamber 13 and a compressor chamber 14.

The fan chamber 13 includes a fan 13a of the air conditioner.

The compressor chamber 14 includes a compressor 14a and a flat electric component box 15.

The electric component box 15 incorporates the printed wiring board 1 as described in the first or second embodiment. The printed wiring board 1 is placed with the surface side down, the electric components 15a being mounted onto the surface side, and with the other side up, the other side is being flat and covered with a copper foil.

In the air conditioner of the fourth embodiment, the electric components 15a are attached to the printed wiring board 1 described in the first or second embodiment, so operational failures of the electric components 15a that would occur due to a soldering failure can be reduced with reliability.

### EXAMPLES

The length A of the leader pattern resist removal portion 5a illustrated in FIG. 2 or 4 can be set to 2.0 mm by way of example.

Further, a size of the lattice-like land 6 illustrated in FIG. 4 can be set to 12.5 mm in length and 6.5 mm in width by way of example.

A width of a lattice pattern may be set as follows by way of example.

(1) Pattern width D of lattice pattern=0.5 mm
(2) Vertical pitch B of lattice patterns=1 mm
(3) Horizontal pitch C of lattice patterns=1 mm

1. A printed wiring board for mounting a surface mounting device thereonto, comprising:
a solder land for mounting the surface mounting device; and
a leader pattern led from the solder land,
wherein only a predetermined portion of the leader pattern is soldered.

2. The printed wiring board according to claim 1, wherein a resist is applied onto the leader pattern not to solder a predetermined portion of the leader pattern, and
the resist is removed from the remaining portion of the leader pattern to solder the remaining portion.

3. The printed wiring board according to claim 1, wherein the portion of the leader pattern to be soldered is formed with a length substantially the same as or twice as long as a length of the solder land.

4. A printed wiring board for mounting a surface mounting device thereonto, comprising:
a solder land for mounting the surface mounting device; and
a solder surface tension reducing land for reducing a surface tension of a solder, which is formed upstream of the solder land as viewed from a direction in which soldering progresses upon a wave soldering process of the printed wiring board.

5. The printed wiring board according to claim 4, wherein a plurality of the solder lands are formed, and
the solder surface tension reducing land is formed only in front of the foremost one of the plurality of solder lands as viewed from a direction in which soldering progresses upon a wave soldering process of the printed wiring board.

6. The printed wiring board according to claim 4, wherein the solder surface tension reducing land has a vertical size substantially the same as or twice as large as a vertical size of the surface mounting device, and a horizontal size substantially the same as or twice as large as a horizontal size of the surface mounting device.

7. The printed wiring board according to claim 1, wherein the surface mounting device is soldered with a lead-free solder.

8. An air conditioner, comprising:
the printed wiring board according to claim 1; and
an electric component box housing the printed wiring board and being located above a compressor chamber.

9. A method of soldering a surface mounting device to a printed wiring board with a wave soldering apparatus, comprising:
forming a solder land for mounting the surface mounting device and a leader pattern led from the solder land on the printed wiring board to solder only a predetermined portion of the leader pattern; and
soldering a leader portion of the surface mounting device to the solder land using the wave soldering apparatus.

10. A method of soldering a surface mounting device to a printed wiring board with a wave soldering apparatus, comprising:
forming a solder land for mounting the surface mounting device on the printed wiring board;
forming a solder surface tension reducing land for reducing a surface tension of a solder on an upstream side of the solder land as viewed from a direction in which soldering progresses with the wave soldering apparatus; and
soldering a leader portion of the surface mounting device to the solder land using the wave soldering apparatus.

11. The method of soldering a surface mounting device to a printed wiring board according to claim 9, wherein the surface mounting device is soldered with a lead-free solder.
